(19) United States
(12) Patent Application Publication
(10) Pub. No.: US 2026/0107849 A1
(43) Pub. Date: Apr. 16, 2026

(54) Two-Chip Solution for Dual/Multiple Power Devices

(71) Applicant: Alpha and Omega Semiconductor International LP, Toronto (CA)

(72) Inventors: Shekar Mallikarjunaswamy, San Jose, CA (US); Shanghui Larry Tu, San Diego, CA (US)

(21) Appl. No.: 19/089,022

(22) Filed: Mar. 25, 2025

Related U.S. Application Data
(63) Continuation-in-part of application No. 18/374,297, filed on Sep. 28, 2023.

(51) Int. Cl. H10W 90/15; H10D 80/30; H10W 70/60; H10W 72/00; H10W 90/00; H10W 90/22

(52) U.S. Cl. CPC H10W 90/15; H10D 80/30; H10W 70/611; H10W 72/07236; H10W 90/754; H10W 90/756; H10W 90/811; H10W 90/22; H10W 90/401; H10W 90/724; H10W 90/726

(57) ABSTRACT

A power device and method of making said power device. The device including a gate controller coupled to a first substrate. A first set of one or more transistor devices is coupled to a second substrate and a second set of one or more transistor devices is also coupled to the second substrate. The first set of transistor devices and second set of transistor devices are communicatively coupled to the gate controller.

### CROSS-REFERENCE TO RELATED APPLICATION

This application is a continuation-in-part of U.S. patent application Ser. No. 18/374,297 filed Sep. 28, 2023, the entire contents of which are incorporated herein by reference for all purposes.

### FIELD OF THE DISCLOSURE

Aspects of the present disclosure relate to Driver-MOSFET (DrMOS) devices specifically aspects of the present disclosure relate to wafer level packaging and drivers in DrMOS devices.

### BACKGROUND OF THE DISCLOSURE

In conventional DrMOS devices transistor drivers are packaged with transistor devices in a multi-chip package. The current popular multi-chip packages include Quad Flat-no lead (QFN) and flip chip, which use bond wires to connect chips within the package to a lead frame. Flip chip packages include the use of a clip to connect the backside of the chip to the lead frame.

FIG. 1A and FIG. 1B schematically depict a prior art flip chip design. As shown, the flip chip package includes a gate controller integrated circuit 101, a high-side metal oxide semiconductor field effect transistor (MOSFET) 103, low-side MOSFET 102, lead frame 107, and backside clip 110. The gate of the low-side MOSFET 102 includes a large gate contact pad 104 that is required for the gate contact pad to have sufficient area for connection to the transistor driver 101. A large soldered joint 111 makes the connection between the gate contact pad 104 and the lead frame 107. Metal bond wires 106 connect the lead frame to the transistor driver allowing the transistor to send signals to the gate contact pad 104 of the low-side MOSFET 102 through a large soldered joint 111. The high-side MOSFET 103 also includes a large gate contact pad 105; a high-side gate bond wire 108 connects the gate contact pad 105 to the high-side gate control output node of the transistor driver 101. The large gate contact pads take up significant amounts of space in the low-side MOSFET 102 and the High-side MOSFET 103. In particular, the space underneath the gate contact pads is wasted because there is no active area under the gate pads. The transistor driver 101 also includes pads for other control inputs which are connected to the lead frame 107 by bond wires 109.

As seen in FIG. 1B a backside clip 110 connects the source of the high-side MOSFET 103 to the drain low-side MOSFET 102 to the VSWH pin-out of the lead frame 107. Bond wires require space within the device package because each wire must be separated with a gap large enough to ensure there is no arcing between leads and the pad must be large enough on each device that a bond can be made. Additionally, the bond wires have a large inductance compared to thin metal leads. The lead frame and clip also present a size disadvantage as a metal clip must be provided with enough strength to hold contact with the backside of the chip. Finally, the large single bond pads create an issue because the gate impedance is non-uniform which causes non-uniform switching of the transistor device.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1A is a top-down schematic diagram of a prior art flip chip design.

FIG. 1B is a side view of the prior art flip chip design.

FIG. 2 is a top-down view of the redistribution layer (RDL) of a transistor device according to aspects of the present disclosure.

FIG. 3 is a top-down view of the RDL of a DRMOS device having a distributed gate drive with a single gate bus for the gates of each MOSFET according to aspects of the present disclosure.

FIG. 4 is a top-down view of the RDL of a DRMOS device having a distributed gate drive with multiple proportionally distributed gate busses for the gates of each MOSFET according to aspects of the present disclosure.

FIG. 5 is a top-down view of the RDL of a DRMOS device having a distributed gate drive with multiple equally distributed gate busses for the gate electrode contact regions located on two top sides of each FET device according to aspects of the present disclosure.

FIG. 6 is a top-down view of the RDL of a DRMOS device having a distributed gate drive with multiple proportionally distributed gate busses for the gate electrode contact regions located on two top sides of each FET device including a sense FET according to aspects of the present disclosure.

FIG. 7 is a top-down view of the RDL of a DRMOS device having a FET device integrated with the gate control and a distributed gate drive with multiple proportionally distributed gate busses for the gate electrode contact regions located on a top edge of the separate FET device according to aspects of the present disclosure.

FIG. 8 is a top-down view of the RDL of a DRMOS device having integrated trench capacitors in the semiconductor wafer according to aspects of the present disclosure.

FIG. 9 is a top-down view of the RDL of a DRMOS device illustrating the distributed gate drivers according to aspects of the present disclosure.

FIG. 10 is a top-down view of the RDL of a DRMOS device including split FET devices according to aspects of the present disclosure.

FIG. 11A is a cutaway side view of a shielded gate trench (SGT) MOSFET device in an implementation of the DRMOS according to aspects of the present disclosure taken along line A-A of FIG. 10.

FIG. 11B is a cutaway side view of a shielded gate trench (SGT) MOSFET device in an implementation of the DRMOS according to aspects of the present disclosure taken along line B-B of FIG. 10.

FIG. 12A is a cutaway side view of a planar gate MOSFET device in an implementation of the DRMOS according to aspects of the present disclosure taken along line A-A of FIG. 10.

FIG. 12B is a cutaway side view of a planar gate MOSFET device in an implementation of the DRMOS according to aspects of the present disclosure taken along line B-B of FIG. 10.

FIG. 13 is a top-down diagram depicting a two-chip solution according to aspects of the present disclosure.

FIG. 14 is a top-down diagram depicting a two-chip solution with distributed transistor drivers according to aspects of the present disclosure.

FIG. 15A is a top-down diagram depicting a two-chip device package with molded interconnect substrate (MIS) according to aspects of the present disclosure.

FIG. 15B is a side view diagram of the two-chip device package with MIS according to aspects of the present disclosure.

FIG. 16A is a top-down diagram depicting a two-chip device package with flip chip gate controller and molded interconnect substrate (MIS) according to aspects of the present disclosure.

FIG. 16B is a side view diagram of the two-chip device package with flip chip gate controller and MIS according to aspects of the present disclosure.

FIG. 17A is a top-down diagram depicting a two-chip device package with traditional lead frame according to aspects of the present disclosure.

FIG. 17B is a side view diagram of the two-chip device package with traditional lead frame according to aspects of the present disclosure.

FIG. 18A is a top-down diagram depicting a two-chip device package with flip chip gate controller and traditional lead frame according to aspects of the present disclosure.

FIG. 18B is a side view diagram of the two-chip device package with flip chip gate controller and traditional lead frame according to aspects of the present disclosure.

FIG. 19 is a side view diagram of a three-chip device package arranged with three-dimensional stacking according to aspects of the present disclosure.

FIG. 20 is a side view diagram of a four-chip device packaged arranged with three-dimensional stacking according to aspects of the present disclosure.

FIG. 21 is a flow diagram depicting a process for making the two-chip solution according to aspects of the present disclosure.

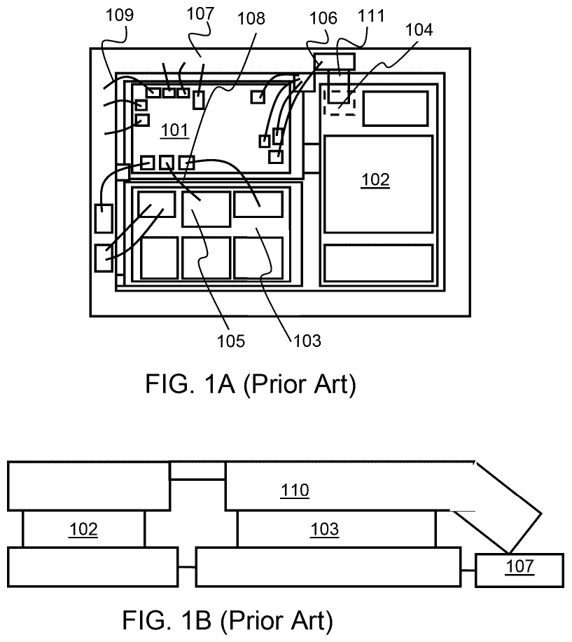

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the present disclosure. Accordingly, example embodiments of the present disclosure described below are set forth without any loss of generality to, and without imposing limitations upon, the claimed invention.

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon may be used in MOSFET devices in accordance with aspects of the present disclosure.

In the following Detailed Description, reference is made to the accompanying drawings, which form a part hereof, and which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n-material. Similarly, a p+ material has a higher p type net dopant (e.g., hole) concentration than a p material, and a p material has a higher concentration than a p− material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants less than about 10¹⁵/cm³ may be regarded as “lightly doped” and a concentration of dopants greater than about 10¹⁷/cm³ may be regarded as “heavily doped”.

According to aspects of the present disclosure an improved DrMOS device may be created through the use of wafer level or panel level packaging with distributed contact placement in transistor devices providing a more uniform transistor device switching and reduced device area. Additionally, the use of distributed gate drive in a wafer level or panel level package may also improve the DrMOS device, reducing parasitic inductance, reducing device area, and improving robustness by splitting points of failure between multiple drivers. Finally, the use of both distributed contact placement and the distributed gate drive in a wafer level or panel level package may provide an enhanced DrMOS device with all of the previously mentioned benefits.

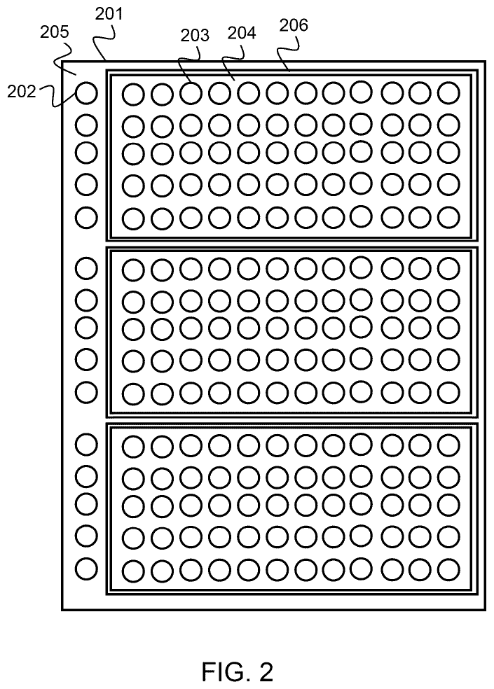

FIG. 2 is a top-down view of the redistribution layer (RDL) of a transistor device according to aspects of the present disclosure. As shown the transistor device 201 includes a gate RDL or gate top metal 205. The transistor device includes a source RDL or source top metal 204. Separation regions 206 insulate the source RDL or top metal from a gate RDL or top metal 205.

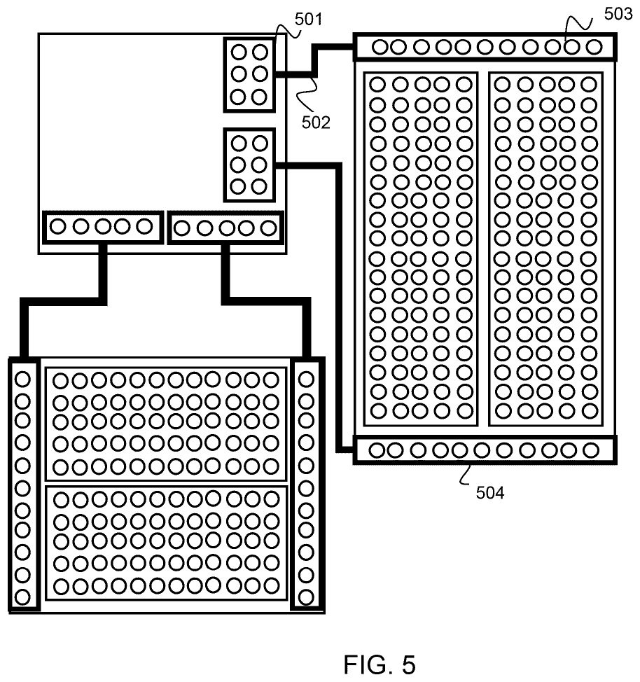

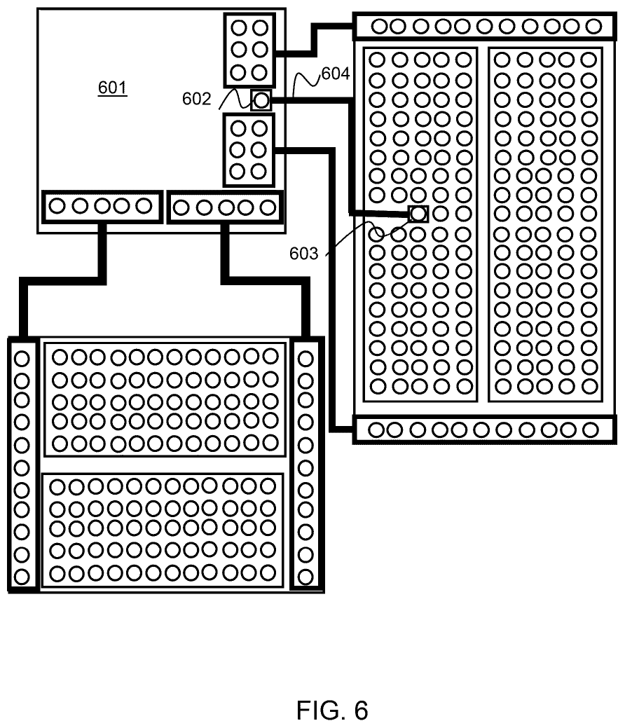

The gate RDL or top metal 205 as shown includes plated gate vias 202 that provide an electrically conductive pathway through a gate insulating layer to the gate electrode. The gate electrode material may be distributed through the substrate composition to create a gate contact region along a top edge of the substrate composition. It should be noted that implementations are not limited to a gate contact region along a single top edge and the gate contact region may in one or more horizontal lines on top of the substrate composition in any area or run along two top edges as shown in FIG. 5 and FIG. 6. Two or more vias through the gate insulating material expose portions of the gate electrode material in the gate contact region and conductive material of the plated gate vias 202 makes conductive contact with a portion of the gate electrode material on the edge of the transistor device. The two or more vias may be proportionally distributed over the gate contact region. There may be a sufficient number of vias of a suitable size to proportionally distribute voltage through the gate electrode. In some implementations the plated gate vias 202 may be filled with the conductive material of the gate RDL or gate metal layer. The gate RDL or gate metal layer may be made from, for example and without limitation, copper, aluminum, iron, tungsten, lead, or any alloy thereof.

Here when discussing the RDLs, reference to a source RDL, gate RDL, or drain RDL may be made, these refer to the RDL material in the RDL conductively coupled to the preceding element. For example, the gate RDL is the RDL material conductively coupled to the gate electrode through vias in a gate insulating layer. Similarly, a source RDL is the RDL material conductively coupled to the source regions and body regions through vias in a source insulating layer and a drain RDL material conductively coupled to the drain region through vias in a drain insulating layer. It should be understood that the source RDL and gate RDL may be different traces on the same RDL layer or traces on different RDL layers.

The source RDL or top metal 204 as depicted includes plated source vias 203 through a source insulating layer to a source contact. The source insulating layer and the gate insulating layer may be formed from the same material and formed at the same time. Thus, in some implementations the gate insulating layer and source insulating layer may be the same layer over the device substrate composition. The source and gate insulating layers may be made of an oxide, such as silicon dioxide, or another material, such as silicon nitride, which may be formed on top of gate electrode material, e.g., polysilicon or silicide. Two or more vias through the source insulating material expose the source region in the substrate composition and conductive material of the plated source vias 203 makes conductive contact with a portion of the source region. The two or more plated source vias may be proportionally distributed over the source RDL or Source metal. There may be a sufficient number of vias to proportionally distribute voltage through the gate region. Additionally, the plated source vias 203 may make conductive contact with a body region of the substrate composition forming the so called anti-parallel diode of a MOSFET device. In some implementations the plated source vias 203 may be filled with the conductive material of the source RDL or source metal layer. The source RDL or source metal layer may be made from for example and without limitation, copper, aluminum, iron, tungsten, lead, or any alloy thereof.

The distributed vias may improve device switching by more evenly distributing the contacts with the gate electrodes than implementations utilizing a single gate pad.

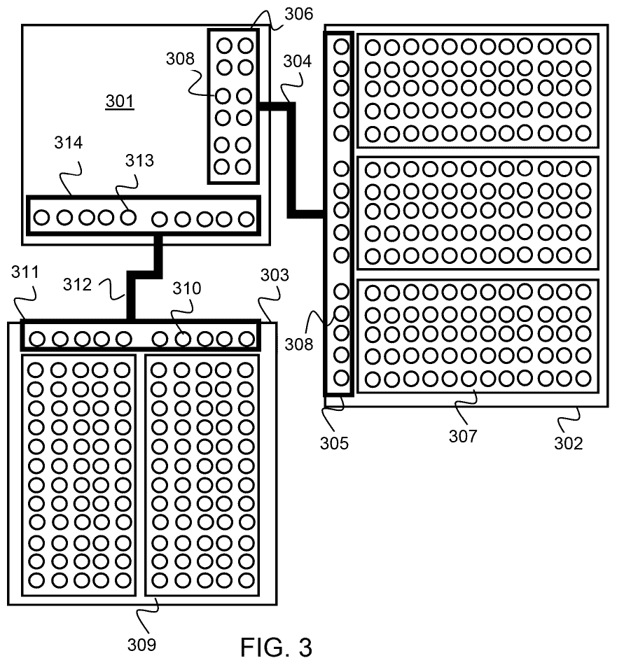

FIG. 3 is a top-down view of the RDL of a DRMOS device having a distributed gate drive with a single gate bus for the gates of each MOSFET according to aspects of the present disclosure. As shown, the first FET device 302 and the second FET device 303 are each connected to the gate driver output nodes of the gate controller 301 via a single bus for each FET device. The gate controller 301 may be for example and without limitation a gate controller integrated circuit. The gate controller 301 may include gate drivers that are proportionally distributed between gate electrodes. In the example shown there are three gate drivers corresponding to the three gate contacts on the first FET device 302 and plated vias 308 connect the gate drivers to an RDL 306 on the gate controller 301. The RDL 306 conductively couples each of the distributed drivers through the vias 308. A single Bus 304 in the RDL of the device connects the distributed drivers to the first gates of FET 302 through gate RDL 305. First FET device gate plated vias 308 connect the first FET device RDL 305 to the three gate electrodes of the first FET device 302. The first FET source RDL or source metal layer 307 also includes two or more plated vias which make contact with the source region of the FET device 302. As shown, there is a plurality of plated vias in the first FET device RDL or source metal. The distributed drivers improve the failure resistance of this device as it may continue to operate even if one driver fails.

Similarly, the second FET device 303 includes two sets of gate vias through a gate insulating layer that expose the gate electrode of the FET device. Conductive plating of the plated vias 310 connects the Gate RDL 311 to the gate electrodes. A second bus 312 formed from the RDL connects the gate electrodes to gate controller 301. Second plated vias 313 in the gate second gate RDL 314 connect the gate drivers to the second gate RDL 314 and the second bus 312. As shown, the second FET device Source RDL 309 includes a two or more plated vias which make conductive contact with the gate region of the FET device. Here, the first FET device may be a low-side FET and the second FET may be a high-side FET, but aspects of the present disclosure are not so limited, in some implementations the first FET device may be a high-side FET and the second FET device may be a low-side FET. By way of example, the high-side FET and low-side FET may be part of a voltage regulator. Furthermore, in some implementations, the illustrated configuration may be extended to multi-phase configurations where one controller can be connected to multiple low-side and high-side devices. Additionally, while the implementations shown have two or three gate drivers, aspects of the present disclosure are not so limited and there may be any number of gate drivers sufficient to control the FET devices.

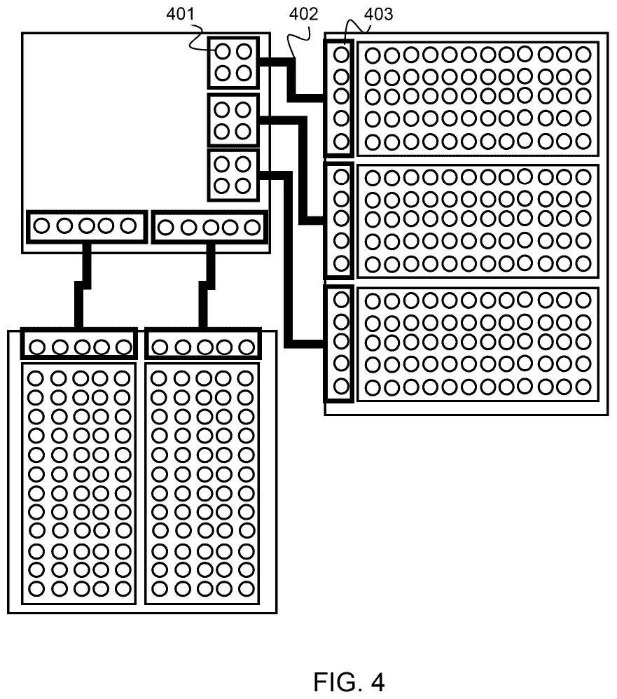

FIG. 4 is a top-down view of the RDL of a DRMOS device having a distributed gate drive with multiple proportionally distributed gate busses for the gates of each MOSFET according to aspects of the present disclosure. As shown, the three buses 402 are made from the RDL material. The three buses may be traces formed from the RDL layer. In alternative implementations the three traces may be wires made from a conductive material. The three buses are proportionally distributed between the three gate drivers of the gate controller. Plated vias 401 made through a gate controller insulating layer conductively couple the RDL material with the output nodes of each of the gate drivers for the first FET. In the implementation shown each output node of the gate drivers is conductively coupled to the RDL material through four plated vias 401. The three buses proportionally distribute connections to the three sets of gate electrode vias 403 in the RDL. Here the gate electrodes are connected by three sets of five plated vias 403 for the first FET Device. Similarly, the gate drivers for the second FET device are proportionally distributed with two busses made from the RDL material and connected between the gate electrode two sets of five gate vias through the gate insulating layer and two sets of five plated gate driver vias through a gate controller insulating layer.

FIG. 5 is a top-down view of the RDL of a DRMOS device having a distributed gate drive with multiple proportionally distributed gate busses for the gate electrode contact regions located on two top sides of each FET device according to aspects of the present disclosure. As shown gate contact regions are located on the first top edge 503 and a second top edge 504. Plated vias in the RDL material make conductive contact with the gate electrodes on the first top edge 503 and second top edge 504. Two buses 502 made from the RDL material conductively couple the gate electrodes with the gate driver output nodes through plated vias made from the RDL material 501. The two buses 502 proportionally distribute connections to the two gate contact regions and two gate drivers which are each conductively coupled to the buses through six plated vias.

FIG. 6 is a top-down view of the RDL of a DRMOS device having a distributed gate drive with multiple proportionally distributed gate busses for the gate electrode contact regions located on two top sides of each FET device including a sense FET according to aspects of the present disclosure. Having edge-located contact regions for the gate electrodes allows new possibilities for locations of a sense FET. Typically sense FETs are located on an edge of the device for ease of connection. This provides less than ideal sensing because the sense FET is separated from the rest of the FET device area. As shown, the sense FET source region 603 is located in the middle of the source regions allowing more accurate sensing of the operation. The two edge contact regions, keep RDL material busses out of the way. The sense FET source region is connected to a sense FET RDL material through a conductive via. A special sense gate bus 604 made from the RDL material connects the sense FET source region to a sense FET node of the gate controller IC 601 through a conductive via 602. While the implementation shown includes two edge contact regions for the gate electrode material, aspects of the present disclosure are not so limited. Alternatively, the sense FET located in the middle of source regions may be implemented with a single edge contact region or three or more edge contact regions.

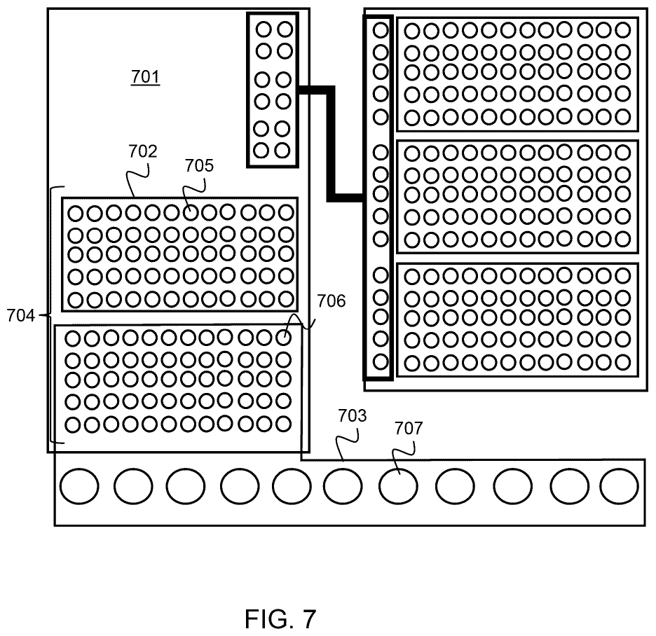

FIG. 7 is a top-down view of the RDL of a DRMOS device having a FET device integrated with the gate control and a distributed gate drive with multiple proportionally distributed gate busses for the gate electrode contact regions located on a top edge of the separate FET device according to aspects of the present disclosure. As shown the gate controller 701 includes an integrated FET 704. The integrated FET may be for example and without limitation the high-side FET. An integrated FET drain RDL 702 may include an RDL having plated vias 705 in conductive contact with the drain region of the integrated FET 704. The plated vias 705 may be proportionally distributed over the drain region of the integrated FET. The integrated FET drain RDL 702 may run to a drain connection node for the DRMOS device. An integrated FET source RDL 703 may make conductive contact with the source regions of the integrated FET 704 through plated vias 706. The integrated FET source RDL 703 may also include plated vias 707 that provide an electrically conductive pathway through a molding material layer to a source connection node for the DRMOS device. Additionally, the DRMOS device may include a separate FET device and distributed drivers similar to those seen in previous implementations.

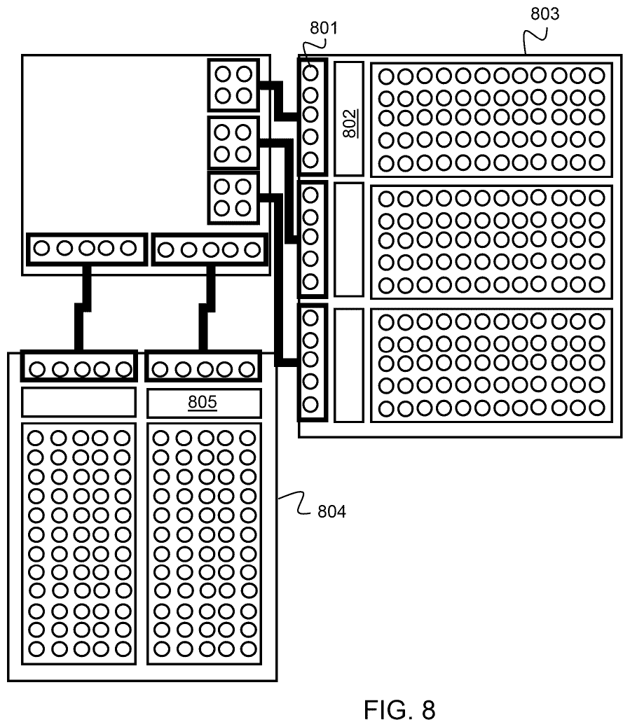

FIG. 8 is a top-down view of the RDL of a DRMOS device having integrated trench capacitors in the semiconductor substrate composition according to aspects of the present disclosure. As shown here, the first FET device 803 includes on-chip trench capacitors 802 formed in the substrate composition of the first FET device. In some alternative implementations the on-chip capacitors may be planar capacitors. The plated vias 801 may be in conductive contact with the gate electrode material in the gate contact region at a top edge of the substrate composition. The trench capacitors may also be in conductive contact with the gate electrode of the gate of the FET device. The second FET device 804 may also include trench capacitors 805 similarly coupled to the gate electrode material. The gate electrode material in the contact region is in conductive contact with the trench capacitors. Here, each distributed gate driver is coupled to a separate trench capacitor through the gate RDL. Aspects of the present disclosure are not so limited and may include for example and without limitation a single trench capacitor structure in conductive contact with each of the gate drivers or multiple trench capacitor structures in conductive contact with a single gate driver.

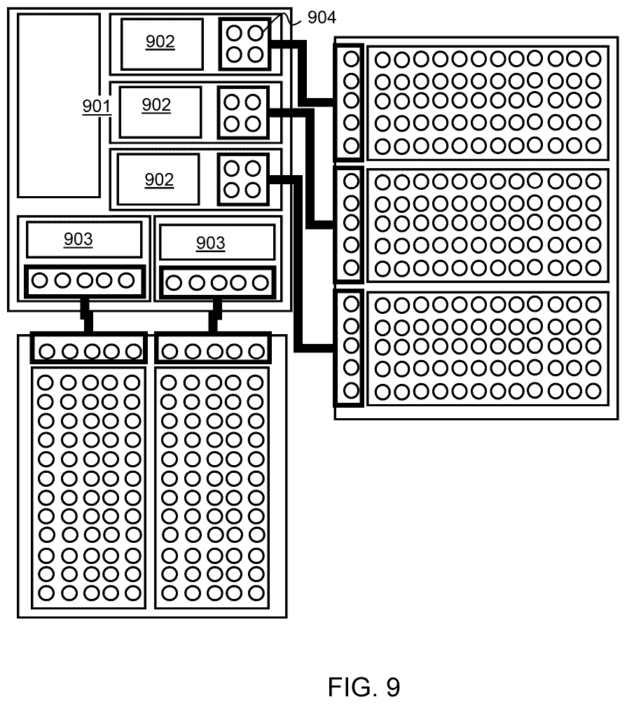

FIG. 9 is a top-down view of the RDL of a DRMOS device illustrating the distributed gate drivers according to aspects of the present disclosure. Here, the gate controller 901 includes gate drivers 902 for the first FET device and the gate drivers 903 for the second FET which are visible. It further can be seen that each of the gate drivers 902 for the first FET device and the gate drivers 903 for the second FET device are coupled to their respective FET devices through plated vias 904. The distributed gate drivers provide redundancy should a driver fail and in implementations that include multiple RDL traces connecting the gate electrode, better distribution of energy to the gate electrodes.

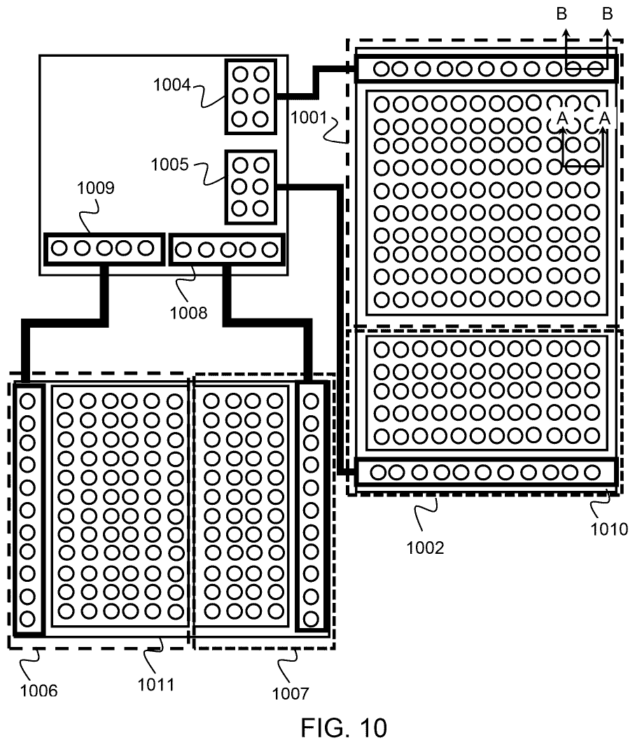

FIG. 10 is a top-down view of the RDL of a DRMOS device including split FET devices according to aspects of the present disclosure. In the implementation shown the first FET device 1010 includes two separate gate structures of uneven size. Shown here the first gate structure 1001 of the First FET device is the larger sized gate which is used in normal device operation.

Here the size of the gate refers to the amount of device area taken up by the gate electrode. The second gate structure 1002 of the first FET device is a smaller sized gate that may be used during light load conditions. In some implementations, the distributed drivers for the first FET may be proportionally distributed between the first gate structure 1001 and the second gate structure 1002. Specifically, a larger FET may have larger distributed drivers than a smaller FET. Shown here a first gate driver is connected to the first gate structure through plated vias to a first gate structure RDL 1004. The second gate driver is connected to the second gate structure through plated vias to a second gate structure RDL 1005.

Similarly, the second FET device 1011 includes two separate gate structures of uneven size. The first gate structure 1006 of the second FET device is the larger sized gate which is used in normal device operation. The second gate structure 1007 of the first FET device is a smaller sized gate that may be used during light load conditions. The distributed drivers for the first FET may also be evenly split between the first gate structure 1006 and the second gate structure 1007. Shown here a first gate driver is connected to the first gate structure through plated vias to a first gate structure RDL 1009. The second gate driver is connected to the second gate structure through plated vias to a second gate structure RDL 1008. As with the first FET device 1010, the distributed drivers for the second FET device 1011 may be proportionally distributed between the first gate structure 1006 and the second gate structure 1007. The larger of the two FETs may have larger distributed drivers than the smaller of the two.

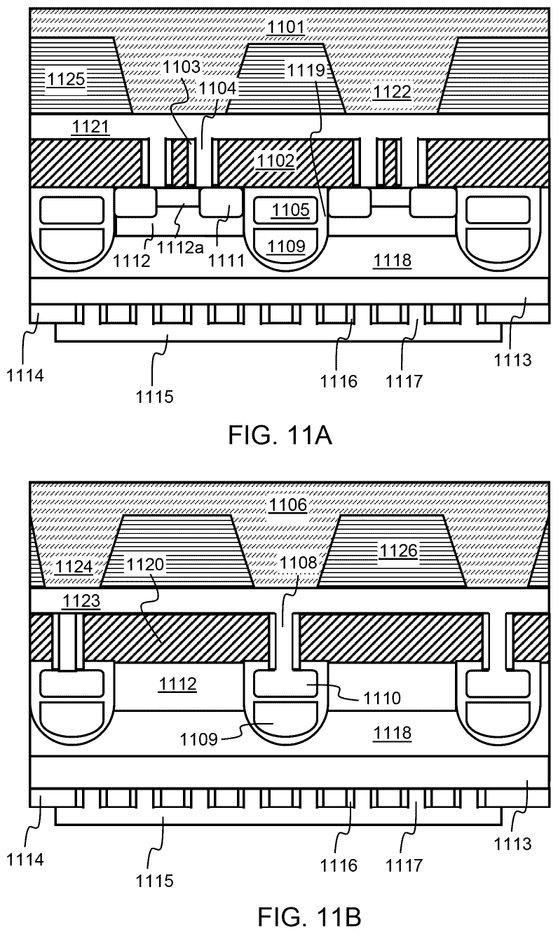

FIG. 11A and FIG. 11B are cutaway side views of a shielded gate trench (SGT) MOSFET device in an implementation of the DRMOS according to aspects of the present disclosure. FIG. 11A depicts a cross-section of the device region under a source region RDL 1101 and FIG. 11B depicts a cross-section of the gate contact region under a gate RDL 1106. As shown, the device includes a substrate composition includes having a substrate layer 1113 heavily doped with ions of the first conductivity type, a drift region 1118 formed on top of the substrate layer lightly doped with ions of the first conductivity type, a body region 1112 formed in the drift region and doped with ions of the second conductivity type. Source regions 1111 are formed in an upper portion of the body region and heavily doped with ions of the first conductivity type. Here, the substrate composition may be a semiconductor material, for example and without limitation, gallium nitride, silicon, or silicon carbide.

The substrate composition includes trenches with a trench insulating layer 1119 lining a surface of each of the trenches. In the implementation shown, a shield electrode 1109 is located over a bottom surface of the trenches on the trench insulating layer 1119. The trench insulating layer 1119 extends over the shield electrode 1109. Gate electrode 1105 is located over the shield electrode 1109 on the trench insulating layer 1119. The trench insulating layer 1119 also covers the gate electrode. It should be noted that each source region 1111 is further located near a side of a trench. Additionally, while an SGT structure is shown, aspects of the present disclosure are not so limited and a trench gate structure may be made by simply excluding the shield electrode. The gate electrodes 1105 are connected to a gate contact region by gate runners 1110, which make electrical contact to a gate RDL 1106 through plated vias 1124 in a molding material layer 1126 to a gate metal layer 1123 and electrically conductive vias 1108 in the gate contact region insulating layer 1120, as shown in FIG. 11B. The shield electrodes 1109 may be conductively coupled to the source region RDL 1101 (not shown). The RDL vias may be formed by laser ablation and may be 20 micrometers in diameter or less.

As shown in FIG. 11B, the gate RDL 1106 extends along a top edge of the substrate composition. The gate RDL 1106 may be formed from the same material as the source region RDL 1101, e.g., through conventional metal deposition and patterning techniques.

A source insulating layer 1102 is located on top of the substrate composition under a source region top metal 1121 and over the source regions 1111 and body regions 1112. Vias 1103 are formed in the source insulating layer exposing a portion of the source region 1111 and a portion of the body region 1112. In some implementations, there may be a doped region 1112a of the second conductivity type between the two source regions 1111 of the first conductivity type. The doped region 1112a is more heavily doped than the body regions 1112. For example, if the body regions or P-type and the source regions are N-type, the doped region 1112a may be doped P+. Alternatively, a shallow trench P+ contact plug may be formed into body region, shorting the N+ and P+/Pbody on the vertical sides of the shallow trench contact plug.

A conductive material may plate the vias 1104, as shown here and the conductive material may fill each via. Here, for example and without limitation the top metal may be aluminum, copper, tungsten, nickel, iron, or any alloy thereof. The conductive via makes conductive contact with both the source region 1111 and the body region 1112 forming the anti-parallel diode. The source top metal 1121 is in conductive contact with the source RDL layer 1101 through plated RDL vias 1122. RDL Vias in the molding material layer 1125 expose the source top metal 1121. The RDL material may plate the sides of the vias and in some implementations, e.g., as shown here, may fill the entire RDL via 1122. The conductive RDL vias 1122 may be proportionally distributed over source region top metal and conductively coupled with the source regions and body regions of the substrate composition.

As shown in FIG. 11B, a gate contact region insulating layer 1120 covers the top of the substrate composition over the gate contact region. Vias 1108 through the gate contact region insulating layer 1120 and trench insulating layer in the gate contact region exposes the gate electrode material that forms the gate runners 1110. Gate RDL 1106 is located on top of the gate contact region insulating layer 1120. The gate RDL 1106 may plate the gate RDL vias 1124 and fill each via. The conductive gate RDL vias 1124 may make conductive contact with the gate metal layer 1123. The gate metal layer 1123 may plate gate contact vias 1108 and fill each via. The conductive gate vias make conductive contact with the gate runners 1110, which are formed in insulated trenches in a similar fashion to the gate electrodes 1105. Portions of the shield electrodes 1109 may also be formed in the trenches along with the gate runners 1110. The RDL vias may be proportionally distributed over the gate contact region 1110. Here the gate electrode material and a shield electrode material may be a conductive material such as poly crystalline silicon.

In the implementation shown, the substrate layer 1118 acts as a backside drain contact region. A drain insulating layer 1114 is formed under the bottom of the substrate composition. Vias 1116 formed through the drain insulating layer 1114 expose the substrate 1118. A drain RDL or metal layer 1115 is located underneath the drain insulating layer 1114. The drain RDL plates the vias 1117 as shown here the drain RDL plates and fills the entire via. Here the drain RDL, source RDL, and gate RDL may be made from a conductive material for example and without limitation copper, aluminum, nickel, tungsten, gold, silver, or any alloy thereof.

It is noted that for implementations that utilize trench capacitors, such as trench capacitors 805 of FIG. 8, the trench capacitors may be formed utilizing both the gate electrode 1105 and shield electrode 1109 in any combination to the source terminal or to the drain terminal. For example, a trench capacitor can be formed between the top gate electrode 1105 as one terminal of the capacitor and source metal as the other terminal of the capacitor (with the shield electrode 1109 tied to a source terminal).

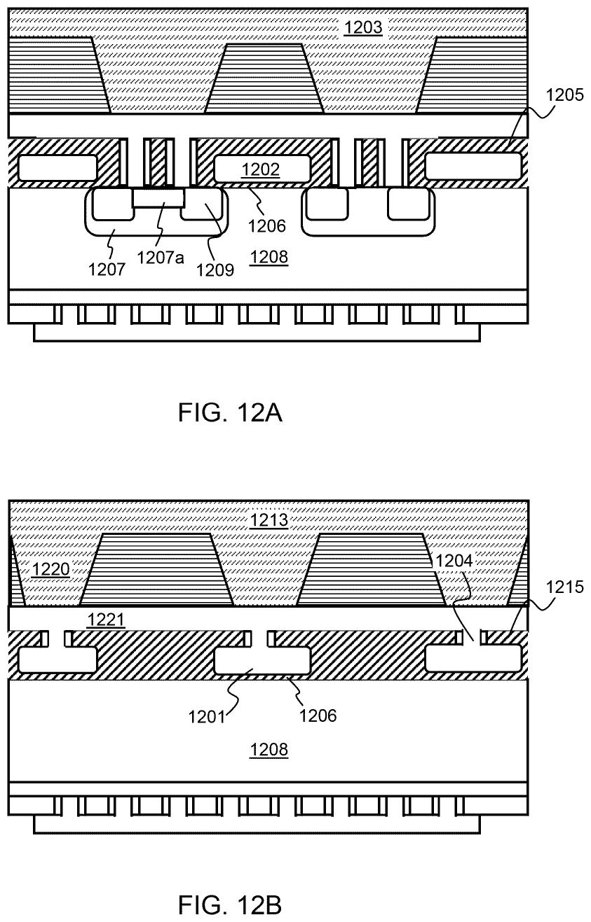

FIG. 12A and FIG. 12B are cutaway side views of a planar gate MOSFET device in an implementation of the DRMOS according to aspects of the present disclosure. FIG. 12A depicts a cross-section of the device region under a source region RDL 1203 and FIG. 12B depicts a cross-section of the gate contact region under a gate RDL 1213. In this implementation body regions 1207 heavily doped with ions of the second conductivity type are formed in body regions 1208 under the source region RDL 1203. Source regions 1209 heavily doped with ions of first conductivity type are formed in the body region. In some implementations, there may be a doped region 1207a of the second conductivity type between the two source regions 1209. The doped region 1207a is more heavily doped than the body region 1207. Alternatively, a shallow trench contact plug of the second conductivity type may be formed into body region, shorting the source and body regions on the vertical sides of the shallow trench contact plug.

Planar gate electrodes 1202 are located over the substrate composition on a planar gate insulating layer 1206. In some implementations, the planar gate insulating layer may wrap around the planar gate electrodes 1202. In an alternative implementation a source insulating layer 1215 may insulate the top and sides of the planar gate electrodes. A portion of the planar gate electrode overlaps the source region and body region.

As shown in FIG. 12B, planar gate runners 1201 make electrical contact between the gate RDL 1213 and the gate electrodes 1202. The gate RDL may be located on the top edge of the substrate composition, e.g., as shown in FIG. 10. A gate electrode contact region insulating layer 1215 is located over top of the substrate composition in the planar gate electrode contact region. The gate RDL 1213 extends over the gate electrode contact region insulating layer 1215. Gate vias 1204 through the gate electrode contact region insulating layer 1215 expose the gate electrode material that forms the planar gate runners 1201. The gate RDL 1213 may plate gate RDL vias 1204 and may fill the entire via making contact with a gate top metal layer 1221. The gate metal layer 1221 may plate the gate vias 1204 and may fill the entire via making contact with the gate electrode material. The RDL vias 1220 may be proportionally distributed over the gate electrode contact region.

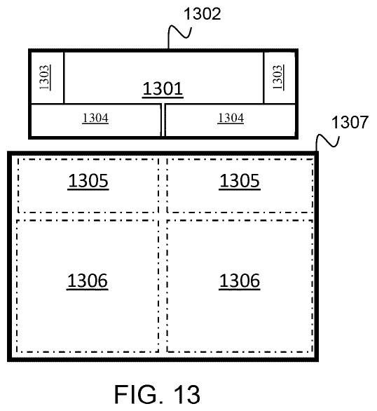

FIG. 13 is a top-down diagram depicting a two-chip solution according to aspects of the present disclosure. As shown, a gate controller 1301 is located on a first substrate 1302. Additionally, in this implementation, the first substrate includes a first set of drivers 1303 and a second set of drivers 1304 for the transistors. These drivers may be for example and without limitation high-side transistor drivers 1303 and low-side transistor drivers 1304 or low-side drivers 1303 and high-side drivers 1304. Additionally, while the first set of drivers 1303 is shown as being relatively smaller than the second set of drivers 1304 it should be understood that each set of drivers should be sized sufficiently to drive the transistor gate they are connected with at the desired voltage and current of the device. Generally, the low-side FET is normally bigger, e.g., 3× to 4× bigger than the high-side FET and the gate driver sizes also scale accordingly.

The gate controller 1301 may be an integrated circuit device formed in the first substrate or created with discrete devices attached to the first substrate in which case the first substrate may provide structural rigidity and may include trace paths for the gate controller. Similarly, the drivers may be created in the first substrate or made with discrete components attached to the first substrate.

In this implementation a first set of transistors 1305 and a second set of transistors 1306 are coupled to a second substrate 1307. The first set of transistors 1305 and second set of transistors 1306 may be created in the second substrate 1307 via successive masking, doping and metallization processes or may be discrete transistors attached to the second substrate in which case the second substrate may provide structural support and may include trace paths for the transistor devices. As shown in each of the first set of transistors 1305 and the second set of transistors 1306 include two transistors but aspects of the present disclosure are not so limited. Each set of transistors may have at least one transistor and may have more than two transistors depending on the implementations. For example, and without limitation, in power converter implementations such as a switch mode buck-boost converter the first set of two transistors 1305 may be the high-side transistors and the second set of two transistors 1306 may be the low-side transistors. In simpler buck boost converter implementations, the high-side transistor set may have single transistor and/or the low-side set may have single transistor. While implementations involving integration into a switch mode power supply are discussed herein it should be understood that applications of the two-chip solution are not so limited, the two-chip solution may be integrated into any application that required controlled switching of transistors. Furthermore, the transistors used in the sets of transistors are not limited to a particular type of transistor, such as a MOSFET, and may be any suitable transistor for the application. Transistor types that may be used in the sets of transistors include, but are not limited to, Bipolar Junction Transistors, Field Effect Transistors, Metal Oxide Semiconductor Field Effect Transistors, Junction Transistors, Insulated Gate Bipolar Transistor, Unipolar, Avalanche Transistors, Schottky Transistors, High Electron Mobility Transistor, and Diffusion Transistors as well as transistors that can be made with wide bandgap semiconductor materials including Lateral Silicon Carbide (SiC) MOSFETs and Gallium Nitride (GaN) High Electron Mobility Transistors (HEMTs).

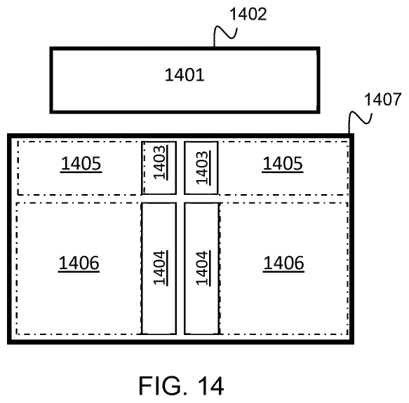

FIG. 14 is a top-down diagram depicting a two-chip solution with distributed transistor drivers according to aspects of the present disclosure. In this implementation the gate controller 1401 is coupled to the first substrate 1402. Unlike the implementation shown in FIG. 13, the drivers are coupled to the second substrate 1407. The first set of gate drivers 1403 and second set of gate drivers 1404 may each be proportionally distributed between the corresponding first set transistors 1405 and the second set of transistors 1406 respectively. For example, and without limitation, the first set of gate drivers 1403 may be proportionately distributed between the transistors in the first set transistors 1405 and the second set of gate drivers 1404 may be proportionately distributed between transistors in the second set of transistors 1406. As shown the gate drivers 1403, 1404 are located in the interior of the second substrate. In some implementations, vias may connect the gate drivers to an interconnect or horizontal bus that diverts the communication channels of the gate drivers to an edge of the second substrate. Alternatively, the gate drivers may be located near an edge of the second substrate. As discussed above, the distributed gate drivers may be connected to the transistor gate through plated vias in an RDL or with regular metal interconnects.

Aspects of the present disclosure include applications of the two-chip approach described hereinabove to both single-phase shift (SPS) and dual phase shift DPS applications. In an SPS application the gate controller has only one switching (SW) output. In a DPS application, by contrast the gate controller has two SW outputs. Furthermore, for DPS, there are two different sets of high-side FETs and low-side FETs that are controlled and operated in certain synchronous fashion. For SPS applications, a mirror image arrangement of the drivers, high-side FETs and low-side FETs, e.g., as shown in FIG. 14, may provide some advantage in term of metal and package connections.

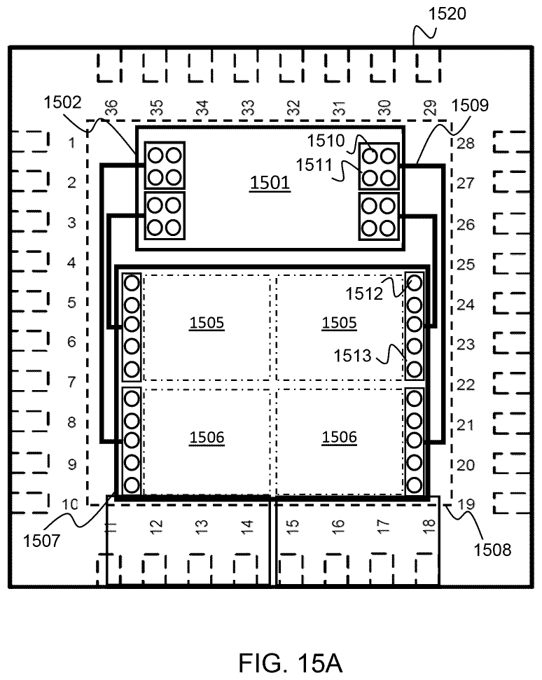

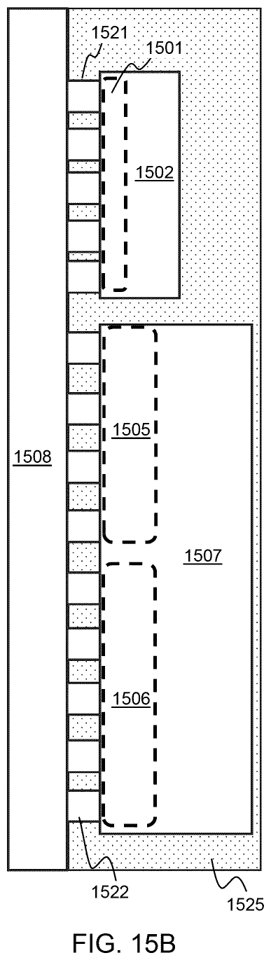

FIG. 15A is a top-down diagram depicting a two-chip device package with molded interconnect substrate (MIS) according to aspects of the present disclosure. An MIS substrate is similar in configuration to a printed circuit board (PCB), however the manufacturing process for MIS allows for much smaller conductive traces and bond pads. An MIS substrate is generally manufactured in layers using photolithography and etch processes that are much like those used to form the upper metal layer interconnects in semiconductor device processing. Typically, metal, e.g., copper, interconnects are built up on a carrier substrate in a series of plating, lithography and etching processes. Spaces between the metal interconnects at various layers are filled with molding compound. The molding compound is ground down and the carrier substrate is removed to expose contacts to the interconnects.

In this implementation the gate controller 1501 on the first substrate 1502 is communicatively coupled with the first set of transistor devices 1505 and second set of transistor device 1506 on the second substrate 1507 through conductive traces 1509 in the MIS 1508. As discussed above, the first substrate 1502 may include sets of gate driver for the sets of transistors or alternatively the second substrate may include the sets of the second substrate 1507 may include the sets of gate drivers for clarity the gate drivers have been omitted from this diagram.

The conductive traces may include conductive contact pads 1511 which connect conductive pillars to the conductive traces in the MIS 1508. The conductive pillars may be connected to conductive plated vias 1510 in the substrate to allow signals to flow from the gate controller (in some implementations through the gate drivers) through the conductive traces to the transistors on the second substrate. The conductive traces and conductive pillars may be made from any suitable conductive material for example and without limitation a metal such as copper, iron, nickel, aluminum, lead or an alloy thereof, a conductive non-metal such as a graphite, or a doped conductive material such as n-doped polycrystalline silicon. Similarly, the vias 1510 may be plated and/or filled with a conductive material as described above.

The conductive traces 1509 may also include conductive second chip contact pads 1513. The conductive second chip contact pads 1513 are connected to second chip conductive pillars which may connect conductive vias 1512 of the second chip 1507 to the transistor devices 1505, 1506 and/or gate drivers (not shown) on the second chip 1507. As shown there may be conductive traces 1509 and contact pads 1511, 1513 corresponding to each transistor device in the sets of transistor devices. Alternatively, there may be contact pads and conductive traces for each gate driver. In yet other alternative implementations, each conductive pillar may have a corresponding contact pad. Furthermore, it should be understood that depending on the needs of the device there may be any number of conductive trace pillars and pads sufficient to control the transistors.

Additionally, the device may include conductive input traces and conductive output traces which are not depicted in the simplified drawings. The conductive inputs traces may electrically couple power inputs and power outputs of the transistors 1505, 1506 on the second chip 1507 to device input pads and output pads in the MIS and in some implementations located on the edge of the device package 1520 as shown. The input traces may also communicatively couple communication pads in the MIS to communication inputs of the gate controller. Additionally, the input traces may electrically couple a supply power input of the gate controller 1501 to a power supply input pad in the MIS 1508, which may be located near the edge of the device package 1520 as shown.

FIG. 15B is a side view diagram of the two-chip device package with MIS according to aspects of the present disclosure. As shown a set of first substrate conductive pillars 1521 may connect the gate controller 1501 on the first substrate 1502 to traces in the MIS 1508. As shown, the gate controller 1501 here is formed with some devices on top of the first substrate and some devices in the first substrate. For example, and without limitation, silicon transistors may be formed in the first substrate, conductive circuitry may be formed on top of the first substrate and devices such as inductors and capacitors may be attached to the top of the first substrate or alternatively formed within. In some implementations, instead of circuitry on top of the substrate, the circuitry may be part of an RDL underneath the substrate. Additionally, in some implementations, devices such as (without limitation) capacitors, diodes and resistors may also be formed in the substrate. Second substrate conductive pillars 1522 may connect the transistors 1505, 1506 (and/or gate drivers not shown) on the second substrate 1507 to traces in the MIS 1508. In the implementation shown in FIG. 15B, the first substrate 1502 is flipped so that the topside connections to the gate controller 1501 may be made directly to electrically conductive pads on the conductive pillars 1521. As shown in FIG. 15B, the second substrate 1507 is also flipped so that topside connections to the first set of transistor devices 1505 and second set of transistor devices 1506 on may be made directly to conductive, e.g., copper, pads on the conductive pillars 1521. The substrates 1502, 1507 along with any external components mounted thereto may optionally be encapsulated in molding compound 1525, as is commonly done.

The transistors and/or gate controller may include a High-Electron-Mobility transistor (HEMT) which has a heterojunction between two different materials. Thus, in some implementations the transistors and/or gate controller may be formed in and on the substrate with a second material. Materials of the substrate and second material may include for example and without limitation: Silicon, Germanium, Gallium, Indium, Carbon, Silicon Carbide, Silicon Nitride, Silicon Arsenide, Gallium Arsenide, Aluminum Gallium Arsenide, Gallium Nitride, Indium Gallium Arsenide, Indium Gallium Nitride, Aluminum Gallium Nitride, Silicon Germanium, Indium Phosphide, and Aluminum Oxide. Additionally, an advantage of this two-substrate solution for gate controller and power transistor device is that the gate controller may be made with a different material than the first set of transistors and the second set of transistors. For example, and without limitation, the first substrate may be made from a first material such as silicon and the second substrate may be made from a second, different, material such as silicon carbide. An advantage of this technique may be the creation and use of low-cost silicon gate controllers with high breakdown resistance transistors, e.g. silicon carbide. Additionally, another advantage of this solution is that large and less expensive process nodes may be used for relatively simple sets of transistors and smaller process nodes may be used for the more complex gate controller. For example, and without limitation, the gate controller may have a minimum feature size of 55 nanometers and the sets of transistors may have a minimum feature size between 0.14 micron and 0.2 microns. Finally, in some implementations the MIS may be replaced with a film such as a flexible polyimide film material, additionally the conductive pillars may be made from a suitable material for the film.

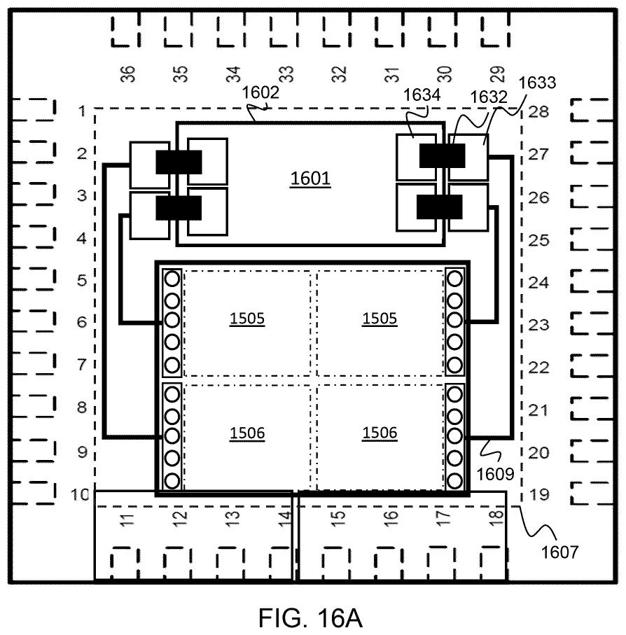

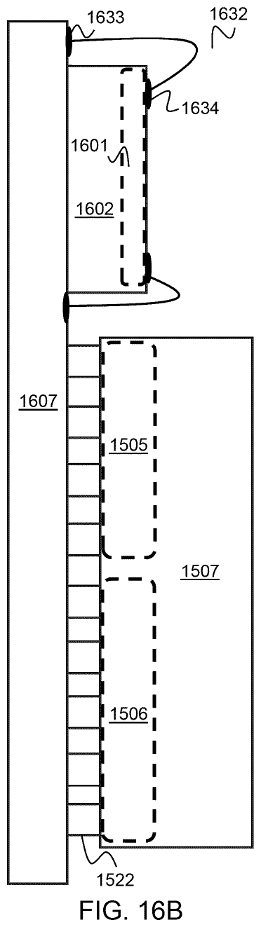

In alternative implementations, it is possible to use a flip chip configuration for one of the two substrates 1502, 1507 but not the other. The non-flipped chip could sit on top of MIS with connections from the top side of the non-flipped chip being made to conductive pads in the MIS via bond pads and wire bonds. An example of such an implementation is depicted in FIGS. 16A-16B.

FIG. 16A is a top-down diagram depicting a two-chip device package with a gate controller and molded interconnect substrate (MIS) according to aspects of the present disclosure. This is similar to the implementation shown in FIGS. 15A and 15B except that a gate controller 1601 has not been flipped leaving contact pads 1634 for wire bonds 1632 exposed. The wire bonds 1632 connect the gate controller contact pads 1634 to the MIS contact pads 1633 allowing electrical signals to pass from the gate controller 1601 (and in some implementations gate drivers) through conductive traces 1609 in the MIS 1607 and to the transistors 1505, 1506 on the second substrate. The wire bonds 1632 may be made from any suitable wire bond material for example and without limitation, gold, silver, copper, aluminum or any alloy thereof.

FIG. 16B is a side view diagram of the two-chip device package with gate controller and MIS according to aspects of the present disclosure. As can be seen the non-flipped orientation of the first substrate 1602 locates the gate controller 1601 on the surface of the first substrate 1602 away from MIS 1607 unlike in FIGS. 15A and 15B. The flipped orientation of the second substate 1507 locates the transistors 1505, 1506 next to the MIS 1607. Connection may be made between the transistors 1505, 1506 and MIS 1607 via copper pillars 1522 and contact pads (not shown) on the flipped surface of the second substrate 1507. The substrates 1602, 1507 along with any external components mounted thereto may be encapsulated in molding compound, as shown in FIG. 15B. The molding compound is not shown in FIG. 16B for the sake of clarity.

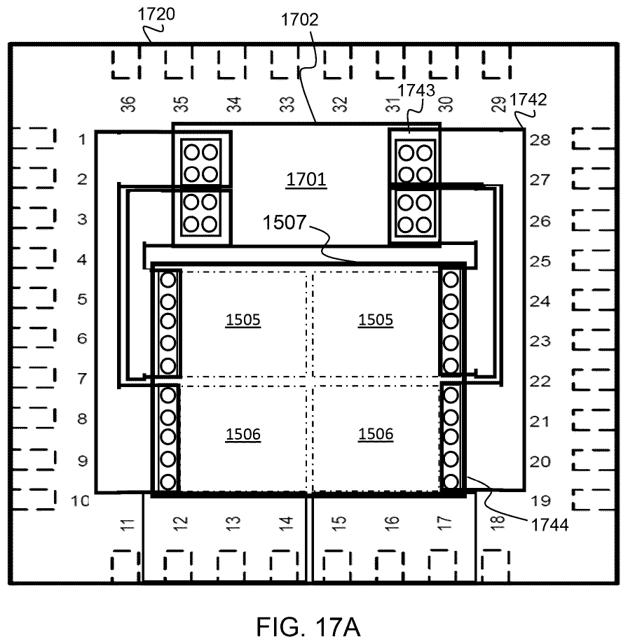

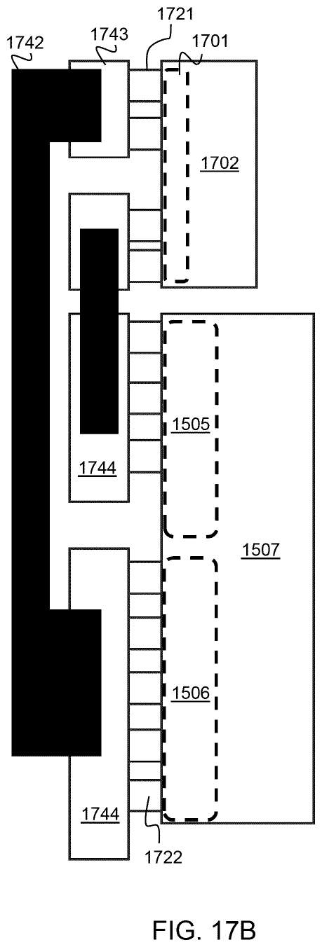

FIG. 17A is a top-down diagram depicting a two-chip device package with traditional lead frame according to aspects of the present disclosure. This implementation is similar to that seen in FIG. 15A but uses lead frame packaging instead of conductive traces in molding material. The lead frame packaging may use conductive bus bars 1742 also referred to as leads to connect the gate controller 1701 on the first substrate 1702 with the transistors 1505, 1506 on the second substrate 1507. The bus bars 1742 may be supported by an outer frame 1720 of the device. The bus bars 1742 may include first substrate bus bar contacts 1743 which provide a connection point for the conductive pillars that may connect to conductive vias and gate controller on the first substrate. Additionally, the bus bars may also include second substrate bus bar contacts 1744 which provide a connection point for the conductive pillars that may connect to conductive vias and the sets of transistors on the second substrate 1507.

Similar to as discussed above with conductive trace, the device may include conductive input bus bars and conductive output bus bars which are not depicted in the simplified drawings. The conductive inputs bus bars may electrically couple power inputs and power outputs of the transistors 1505 1506 on the second chip 1507 to device input pads and output pads on the device frame 1720 as shown. The input bus bars may also communicatively couple communication pads on the device frame 1720 to communication inputs of the gate controller. Additionally, the input bus bars may electrically couple a supply power input of the gate controller to a power supply input pad on the device frame 1720 as shown.

FIG. 17B is a side view diagram of the two-chip device package with traditional lead frame according to aspects of the present disclosure. From this angle the first substrate bus bar contacts 1743 can clearly be seen connecting the bus bars 1742 to the first substrate 1702 and the gate controller 1701 through the conductive pillars 1721. Here the gate controller 1701 on the first substrate is formed within the first substrate. Additionally, the second substrate bus bar contacts 1744 can also be seen connecting the bus bars 1742 to the second substrate 1507 and the first set of transistors 1505 and second set of transistors 1506 through the conductive pillars 1722. As in FIG. 15A and FIG. 15B both the first substrate 1702 and the second substrate 1507 are in a flipped-chip configuration allowing direct contact between the contact pads on the front side of the second substrate and the conductive pillars 1722. The substrates 1702, 1507 along with any external components mounted thereto may be encapsulated in molding compound, as shown in FIG. 15B. The molding compound is not shown in FIG. 17B for the sake of clarity.

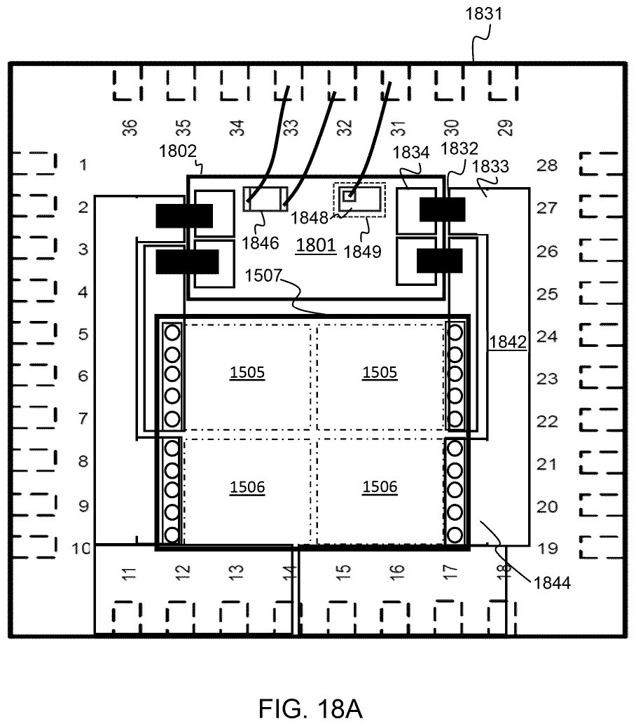

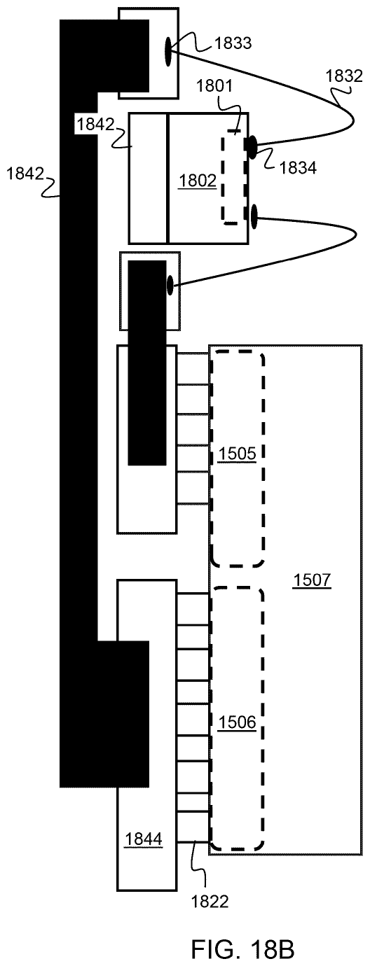

FIG. 18A is a top-down diagram depicting a two-chip device package with flip chip gate controller and traditional lead frame 1831 according to aspects of the present disclosure. This implementation is similar to the implementation described in FIG. 17A, and 17B except that gate controller 1801 has not been flipped leaving contact pads 1834 exposed for wire bonds 1832. The wire bonds 1832 connect the gate controller contact pads 1834 to the bus bar contact pads 1833 allowing electrical signals to pass from the gate controller 1801 (and in some implementations gate drivers) through the bus bars 1842 and to the transistors 1505, 1506 on the second substrate. The wire bonds 1832 may be made from any suitable wire bond material for example and without limitation, gold, silver, copper, aluminum or any alloy thereof. Here the bus bars may include second substrate bus bar contacts 1844 that provide a connection point for the conductive pillars that may connect to conductive vias and the sets of transistors on the second substrate 1507.

In some implementations, one or more discrete electronic components 1846, 1848 may optionally be mounted directly onto the backside of the dies without having to make connections via an MIS. By way of example, such discrete electronic components may include capacitors, diodes, e.g., transient voltage suppressor (TVS) diodes, heat sinks, and the like. In some implementations, one or more surface mount electronic components 1846 may be attached to the backside of the die for the gate controller die 1801 (i.e., the first substrate 1502) and connected to the lead frame 1831 by wire bonds. The surface mount component(s) 1846 may be capacitors, diodes, resistors, or transistors. Alternatively, one or more back-to-back mount components 1848 may be mounted, e.g., by soldering to a backside metal contact 1849 on the gate controller 1801. By way of example, the back-to-back mount component may be a capacitor, inductor, diode, or resistor having two terminals. One terminal makes electrical contact to the gate controller via the backside metal 1849 and another makes contact to the lead frame 1831 through wire bonds. Although FIG. 18A shows discrete components mounted to the backside of the gate controller 1801, aspects of the present disclosure are not so limited. In alternative implementations, discrete components may be similarly mounted to the backside of the transistor die, i.e., the second substrate 1507.

FIG. 18B is a side view diagram of the two-chip device package with flip chip gate controller and traditional lead frame according to aspects of the present disclosure. As can be seen the non-flipped orientation locates the gate controller 1801 on the surface of the first substrate 1802 next to support board 1850 unlike in FIGS. 17A and 17B. As in FIG. 16B, the first substrate 1802 is not flipped for wire bonding while the second substrate 1507 is flipped for connection to the lead frame 1831 via conductive pillars 1822. The substrates 1802, 1507 along with any external components mounted thereto may be encapsulated in molding compound, as shown in FIG. 15B. The molding compound is not shown in FIG. 18B for the sake of clarity.

Aspects of the present disclosure include implementations in which a (non-flipped) external component is placed on top of a flipped chip component and the external component is connected to the MIS via wire bonds and bond pads. For an external component with terminals on both top and bottom, e.g., a capacitor, the terminal on one side could be connected directly to the flipped chip via a ground (e.g., PGND) contact on the back side of a flipped chip and the other terminal could be connected to the MIS via wire bond and bond pads.

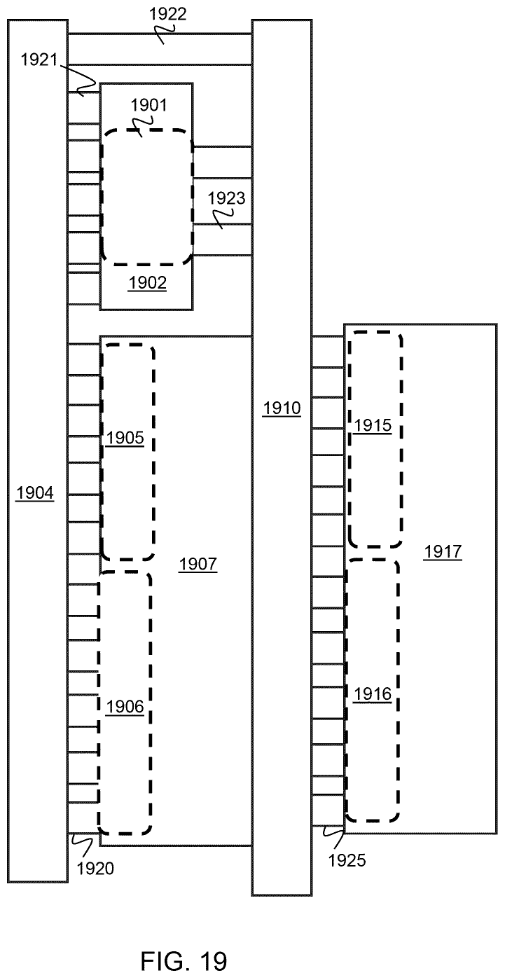

FIG. 19 is a side view diagram of a three-chip device package arranged with three-dimensional stacking according to aspects of the present disclosure. In this implementation, a single gate controller 1901 on a first substrate 1902 and four sets of transistors are shown. A first set of transistors 1905 and second set of transistors 1906 are located on a second substrate 1907 and the third set 1915 and fourth set 1916 of transistors are located on a third substrate 1917. Here, the second substrate 1907 and third substrate 1917 are stacked on top of each other with a second MIS 1910 intervening between the two substrates. All three substrates 1902, 1907, 1917 are in a flipped chip configuration. As discussed above, conductive interconnect pillars 1920 connect the second substrate 1907 to conductive traces in the first MIS 1904. Similarly conductive pillars 1925 connect the third substrate to conductive traces in the second MIS 1910. Additionally conductive interconnect pillars 1922 may connect traces in the first MIS 1904 to the second MIS 1910. Additionally bottom pillars 1923 may connect traces in the second MIS 1910 to connection points in the first substrate 1902 which may allow the gate controller 1901 to control the transistors in the third substrate 1917.

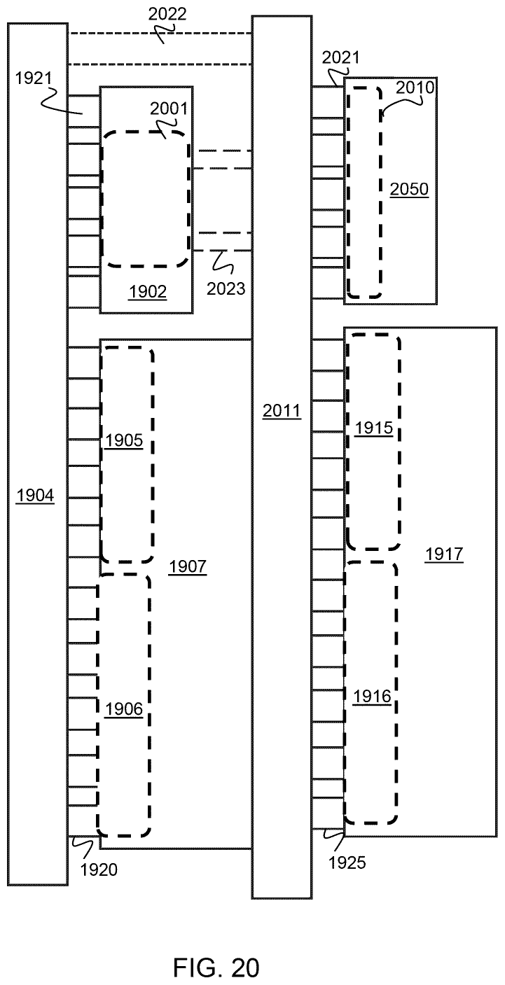

FIG. 20 is a side view diagram of a four-chip device packaged arranged with three-dimensional stacking according to aspects of the present disclosure. In this example, four substrates 1902, 1907, 1917 and 2050 are in flipped-chip configurations. In this implementation a second gate controller 2010 on the fourth substrate 2050 is coupled to the second MIS 2011 creating a complete second power stage on the second MIS 2011 stacked over the first substrate 1902 and the second substrate 1907 and the first MIS 1904. The second power stage may also be communicatively coupled with the first gate controller 1901 through bottom conductive pillars 2023 and/or through a conductive interconnect pillar 2022. As shown conductive pillars 2021 may connect the second gate controller 2010 to traces in the second MIS 2011. The addition of a second gate controller and connections between the second gate controller and first gate controller may allow for synchronization of operation and for one power stage to act as a backup for the other power stage should one fail. Alternatively, such a configuration may be used for the multi-phase operation, e.g., for implementations involving three or more phases.

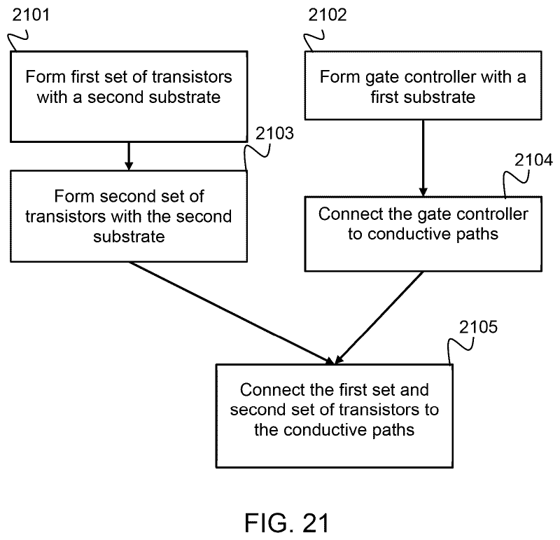

FIG. 21 is a flow diagram depicting a process for making the two-chip solution according to aspects of the present disclosure. As shown here, a first set of transistors may be formed with the second substrate 2101. This may be accomplished by appropriate lithographic processes including masking, doping steps and metallization steps. Additionally, simultaneously, after or before forming the first set of transistors the second set of transistors may also be formed in the second substrate 2103 via appropriate lithographic processes including masking, doping steps and metallization steps.

In another step either before, after or during formation of the transistors the gate controller may be formed in the first substrate 2102. The gate controller may be formed from discrete components attached to the first substrate and connected via traces on the first substrate or formed in the first substrate via appropriate lithographic processes including masking, doping steps and metallization steps.

Bus Bars in a device frame or traces in an MIS or film may be created by wire bonding or lithographic processes to create conductive paths. Next the gate controller on the first substrate may be connected to conductive paths 2104. This may be accomplished by soldering or bonding conductive pads on the first substrate to conductive pillars. The conductive pillars may already be bonded to conductive pads in the conductive paths, or the conductive pillars may first be attached to conductive pads on the substrate and then attached to conductive paths. Once the gate controller IC is attached to the conductive paths, the transistors on the second substrate may be attached to the conductive paths 2105 in a similar manner. Alternatively, the transistors on the second substrate may be connected to the conductive pathways before the gate controller on the first substrate.

As discussed above, it should be understood that the sets of transistors on the second substrate may be formed with a different material such as a different substrate than the gate controller. Additionally, the gate controller may be created with a different minimum or smallest feature size than the sets of transistors.

Improved DrMOS devices of the types described herein may be created with distributed contact placement in transistor devices providing a more uniform transistor device switching and reduced device area. Additionally, the use of distributed gate drive in a wafer level or panel level package may also reduce parasitic inductance, reduce device area, and improve robustness by splitting points of failure between multiple drivers. Finally, the use of both distributed contact placement and the distributed gate drive provides an enhanced DrMOS device with all of the previously mentioned benefits. The two-chip solution provides the additional benefits of reduced assembly cost, smaller package size and advanced packaging styles.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A,” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A power device comprising:
a gate controller coupled to a first substrate;
a first set of one or more transistor devices coupled to a second substrate; and
a second set of one or more transistor devices coupled to the second substrate wherein the first set of transistor devices and second set of transistor devices are communicatively coupled to the gate controller.

2. The power device of claim 1 wherein the gate controller is configured to drive the gates of the first set and second set of transistor devices.

3. The power device of claim 1 wherein the first set of transistor devices and second set of transistor devices each include one or more gate drivers..

4. The power device of claim 3 wherein the one or more gate drivers of the first set of transistor devices is proportionally distributed between the transistor devices in the first set of transistor devices.

5. The power device of claim 3 wherein the one or more gate drivers of the second set of transistor devices is proportionally distributed between the transistor devices in the second set of transistor devices.

6. The power device of claim 1 wherein the first set of transistors are configured for high-side switching in an electric power conversion device and the second set of transistor devices are configured for low-side switching for the electric power conversion device.

7. The power device of claim 1 wherein the gate controller is communicatively coupled to the first set of transistors and the second set of transistors through conductive traces in a molding interconnect substrate or film substrate.

8. The power device of claim 7 wherein the gate controller is connected to the conductive traces in the molding interconnect substrate through at least one bond wire.

9. The power device of clam 1 wherein the gate controller is communicatively coupled to the first set of transistors and the second set of transistors through conductive leads in a lead frame package.

10. The transistor device of claim 9 wherein the gate controller is connected to the conductive leads through at least one bond wire.

11. The power device of claim 1 wherein the first set and second set of transistor devices are formed with a different semiconductor material than the gate controller.

12. The transistor device of claim 1 wherein the first set and second set of transistor devices include at least one material selected from a list consisting of: Silicon, Germanium, Gallium, Indium, Carbon, Silicon Carbide, Silicon Nitride, Silicon Arsenide, Gallium Arsenide, Aluminum Gallium Arsenide, Gallium Nitride, Indium Gallium Arsenide, Indium Gallium Nitride, Aluminum Gallium Nitride, Silicon Germanium, Indium Phosphide, and Aluminum Oxide.

13. The transistor device of claim 1 wherein the gate controller includes at least one material selected from a list consisting of: Silicon, Germanium, Gallium, Indium, Carbon, Silicon Carbide, Silicon Nitride, Silicon Arsenide, Gallium Arsenide, Aluminum Gallium Arsenide, Gallium Nitride, Indium Gallium Arsenide, Indium Gallium Nitride, Aluminum Gallium Nitride, Silicon Germanium, Indium Phosphide, and Aluminum Oxide.

14. The power device of claim 1 wherein the feature size of the Gate Controller is different from the feature size of the first set of transistors and the second set of transistors.

15. The power device of claim 14 wherein the features of the first set of transistors and the second set of transistors are smaller than the features of the gate controller.

16. The power device of clam 1 wherein the gate controller has a smallest feature size of 55 nanometers.

17. The power device of claim 1 wherein the first set of transistors and the second set of transistors have a smallest feature size of between 0.14 micron and 0.2 microns.

18. The power device of claim 1 wherein the first set of transistors are transistors of the type selected from a list consisting of, Bipolar Junction Transistors, Field Effect Transistors, Metal Oxide Semiconductor Field Effect Transistors, Junction Transistor, Insulated Gate Bipolar Transistor, Unipolar, Avalanche Transistors, Schottky Transistors, and Diffusion Transistors.

19. The power device of claim 1 wherein the second set of transistors are transistors of the type selected from a list consisting of, Bipolar Junction Transistors, Field Effect Transistors, Metal Oxide Semiconductor Field Effect Transistors, Junction Transistor, Insulated Gate Bipolar Transistor, Unipolar, Avalanche Transistors, Schottky Transistors, High Electron Mobility Transistor, and Diffusion Transistors.

20. The power device of claim 1, further comprising one or more discrete electronic components mounted to a backside of a die containing the gate controller or a die containing the first and second sets of transistors.

21. The power device of claim 20, wherein the one or more discrete electronic components include one or more surface mount components.

22. The power device of claim 20, wherein the one or more discrete electronic components include one or more back-to-back mount components.

23. A method for making a power device comprising:
forming a gate controller with a first substrate;
forming a first set of one or more transistors with a second substrate;
forming a second set of one or more transistors with the second substrate;
communicatively connecting the first set of transistors and the second set of transistors to the gate controller via a conductive path.

24. The method of claim 21 wherein the gate controller wherein the conductive path includes conductive traces, the method further comprising forming molding material or a film over the conductive traces.

25. The method of claim 21 further comprising, forming a wire bond from a conductive bond wire pad on the gate controller to a conductive pad in the conductive path.

26. The method of claim 21 wherein the conductive path includes conductive leads in a lead frame package.

27. The method of claim 21 wherein forming the first set of transistors and second set of transistors includes forming first and second set with a different substrate material than the gate controller.

28. The method of claim 21 wherein forming the first set of transistors and second set of transistors includes forming the first and second set of transistors with a different feature size than the gate controller.

29. The method of claim 28 wherein the feature size of the first and second set of transistors is smaller than the feature size of the gate controller.
